(19) United States
(12) Patent Application Publication
(10) Pub. No.: US 2013/0319730 A1
(43) Pub. Date: Dec. 5, 2013

(54) FABRIC-TYPE MULTILAYER PRINTED CIRCUIT BOARD AND MANUFACTURING METHOD THEREOF

(71) Applicant: ELECTRONICS & TELECOMMUNICATIONS RESEARCH INST, Daejeon (KR)

(72) Inventors: Yong Ki SON, Daejeon (KR); Ji Eun KIM, Daejeon (KR); Bae Sun KIM, Daejeon (KR); Sung Yong SHIN, Daejeon (KR); Il Yeon CHO, Daejeon (KR)

(73) Assignee: Electronics & Telecommunications Research Institute, Daejeon (KR)

(21) Appl. No.: 13/687,316

(22) Filed: Nov. 28, 2012

(30) Foreign Application Priority Data
May 31, 2012 (KR) 10-2012-0058090

(51) Int. Cl. H05K 1/02; H05K 3/46

(52) U.S. Cl. CPC H05K 1/0298; H05K 3/4602
USPC 174/251; 29/830

(57) ABSTRACT

A fabric-type multilayer PCB and a manufacturing method thereof are provided. The method electrically connects first and second circuit patterns by compressing the first and second unit circuits with a conductor therebetween to introduce the conductor into an insulating layer, and thus can save on manufacturing cost and achieve more precise junction. Also, the fabric-type multilayer PCB includes a conductor that is formed on a fabric material, and directly joined to the first and second circuit patterns to electrically connect the first and second circuit patterns, and thus enables efficient electrical connection. Moreover, even when a shape is deformed by the torsion of flexible fabrics, an electrical connection can be maintained.

### CLAIM FOR PRIORITY

This application claims priority to Korean Patent Application No. 10-2012-0058090 filed on May 31, 2012 in the Korean Intellectual Property Office (KIPO), the entire contents of which are hereby incorporated by reference.

### BACKGROUND

1. Technical Field

Example embodiments of the present invention relate in general to a printed circuit board (PCB) and a manufacturing method thereof, and more specifically, to a fabric-type multilayer PCB and a manufacturing method thereof.

2. Related Art

With recent advancements in the electronic industry, electronic products are becoming miniaturized, thin, and highly densified. In PCBs on which electronic parts included in electronic products are mounted, in order to increase reliability and design density, the structure of a circuit pattern in each layer has a tendency to change into a complicated multilayer structure.

With recent advancements in computing technology, a ubiquitous computing concept is established, and efforts are being made to establish a computing environment independent of time and place. By means of such efforts, an individual carries digital equipment, and moreover, research into wearable computing technology that applies digital equipment to products such as clothes, shoes, etc. that people wear in daily life, is being extensively conducted.

In the field of wearable computing technology, fabric-type PCB technology for applying a circuit to fabrics is proposed as technology for maximizing wearability. Such technology is technology that applies a circuit to the same fabric materials as those of clothing, etc.

Fabrics have excellent flexibility, but, due to such flexibility, it is difficult to apply a circuit to fabrics. Also, users wear clothes in which a fabric-type PCB is formed and lives a daily life, and thus the line of a circuit pattern is easily broken due to interaction with an external environment.

Accordingly, a method that applies a precise circuit having high reliability to fabrics is required.

### SUMMARY

Accordingly, example embodiments of the present invention are provided to substantially obviate one or more problems due to limitations and disadvantages of the related art.

Example embodiments of the present invention provide a method of manufacturing a fabric-type multilayer PCB that introduces a conductor between a plurality of unit circuits, and couples the conductor to the unit circuits by applying compression, in forming a multi-layer unit circuit on a fabric material, thus simplifying a manufacturing process, saving the manufacturing cost, and enabling precise junction.

Example embodiments of the present invention also provide a method of manufacturing a fabric-type multilayer PCB that directly joins a conductor to circuit patterns of each unit circuit to electrically connect the circuit patterns, and thus enables efficient electrical connection and, even when a shape is deformed by the torsion of flexible fabrics, can maintain an electrical connection.

In some example embodiments, a method of manufacturing a fabric-type multilayer PCB includes: providing a first unit circuit formed on a fabric material, a first circuit pattern being exposed on the first unit circuit; providing an insulating layer and a second unit circuit that includes a second circuit pattern disposed under the insulating layer; providing a conductor between the first and second unit circuits; and directly joining and electrically connecting the first and second circuit patterns by compressing the first and second unit circuits with the conductor therebetween to introduce the conductor into the insulating layer.

The providing of a conductor may include: disposing a mask layer on the insulating layer, a hole corresponding to the second circuit pattern being formed in the mask layer; disposing the conductor in the hole of the mask layer; joining the mask layer, in which the conductor is disposed, onto the insulating layer; and removing the mask layer.

The insulating layer may be an adhesive resin layer.

The insulating layer may contain a thermoplastic resin.

The compression may be thermo-compression.

The insulating layer may be an adhesive resin layer. Temperature of the thermo-compression may be higher than or equal to softening temperature of the insulating layer.

An operation of forming the second unit circuit may include: forming the second circuit pattern on a carrier substrate; and forming the insulating layer on the second circuit pattern.

The method may further include removing the carrier substrate of the second unit circuit after electrically connecting the first and second circuit patterns.

In other example embodiments, a fabric-type multilayer PCB includes: a fabric material; a first unit circuit disposed on the fabric material, and including a first circuit pattern; a second unit circuit including a second circuit pattern disposed on the first unit circuit; an insulating layer charged between the first and second circuit patterns; and a conductor joined directly to the first and second circuit patterns to electrically connect the first and second circuit patterns, in the insulating layer.

The insulating layer may be an adhesive resin layer.

### BRIEF DESCRIPTION OF DRAWINGS

Example embodiments of the present invention will become more apparent by describing in detail example embodiments of the present invention with reference to the accompanying drawings, in which:

FIGS. 1 and 2 are sectional views illustrating a method of manufacturing a unit circuit according to an embodiment of the present invention;

FIGS. 3 to 9 are sectional views illustrating a method of manufacturing a fabric-type multilayer PCB according to an embodiment of the present invention; and

FIG. 10 is a sectional view illustrating a fabric-type multilayer PCB including three or more unit circuits according to another embodiment of the present invention.

### DESCRIPTION OF EXAMPLE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions, and particularly, a conductive material, an adhesive, etc. may be exaggerated for clarity. Like numbers refer to like elements throughout the description of the figures.

The invention may have diverse modified embodiments, and thus, example embodiments are illustrated in the drawings and are described in the detailed description of the invention. However, this does not limit the invention within specific embodiments and it should be understood that the invention covers all the modifications, equivalents, and replacements within the idea and technical scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present invention will be described in detail with reference to the accompanying drawings.

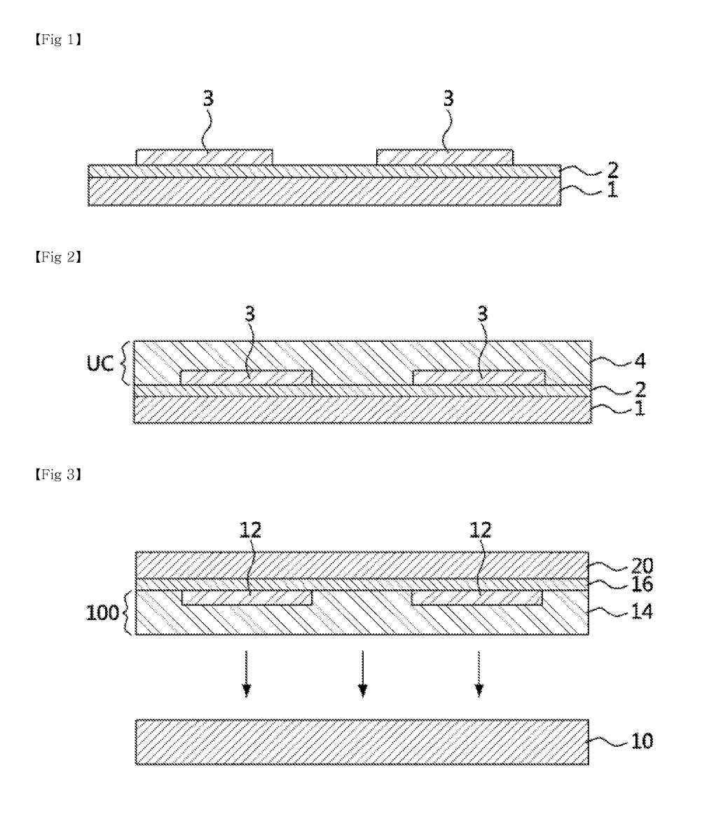

FIGS. 1 and 2 are sectional views illustrating a method of manufacturing a unit circuit according to an embodiment of the present invention.

Referring to FIG. 1, a carrier substrate 1 is provided. The carrier substrate 1 may be an insulating substrate. For example, the carrier substrate 1 may be a polymer film, and specifically, the carrier substrate 1 may be a polyimide film or a polyester film.

A circuit pattern 3 is formed on the carrier substrate 1. A conductive layer may be formed on the carrier pattern 3, and, by selectively removing the conductive layer, the circuit pattern 3 may be formed. The conductive layer may be a metal layer. The metal layer may be formed of one selected from among Cu, Au, Ni, Pd, In, Ti, and Sn. However, the present embodiment is not limited thereto, and the metal layer may be formed of one selected from among various materials through various processes, within the scope that is obvious to those skilled in the art. The conductive layer may be formed by a metal plating process, a process of fixing a metal thin film with an adhesive, or a vacuum evaporation process such as sputtering. Also, the circuit pattern 3 may be formed by depositing a conductive material after a mask may be disposed on the carrier substrate 1.

Before forming the circuit pattern 3, a release layer 2 may be formed on the carrier substrate 1. For example, the release layer 2 may be an insulating polymer material layer. As an example, the insulating polymer material layer may contain polyimide, polyester, or polypropylene.

Referring to FIG. 2, an insulating layer 4 is formed on the circuit pattern 3. The insulating layer 4 may cover the entire surface of the circuit pattern 3. As described above, when the circuit pattern 3 is buried in the insulating layer 4, a contact area between the circuit pattern 3 and the insulating layer 4 is broadened, and thus, adhesive intensity increases.

The insulating layer 4 may be an adhesive layer. In this case, the insulating layer 4 can be reliably adhered to the circuit pattern 3. Furthermore, the insulating layer 4 may be an adhesive resin layer. For example, the insulating layer 4 may contain a thermoplastic resin. As an example, the thermoplastic resin may be polystyrene, polyethylene, polyallylate, or polycarbonate. However, the present embodiment is not limited thereto, and the insulating layer 4 may be formed of one selected from among various materials, within the scope that is obvious to those skilled in the art.

The insulating layer 4 may be formed by using a vacuum press process, or a heat laminate process and a baking process together.

The circuit pattern 3 and the insulating layer 4 may configure a unit circuit UC. However, a process of forming the unit circuit UC is not limited thereto, and the unit circuit UC may be formed through various processes, within the scope that is obvious to those skilled in the art. Also, as described below, the release layer 2 may facilitate separation between the unit circuit UC and the carrier substrate 1.

FIGS. 3 to 9 are sectional views illustrating a method of manufacturing a fabric-type multilayer PCB according to an embodiment of the present invention.

Referring to FIG. 3, the unit circuit UC (which has been described above with reference to FIGS. 1 and 2), namely, a first unit circuit 100 is provided onto a fabric material 10. The first unit circuit 100, as described above with reference to FIGS. 1 and 2, includes a first circuit pattern 12 and the insulating layer 14. Furthermore, the first unit circuit 100 may be disposed on a carrier substrate 20, and the release layer 16 may be disposed between the carrier substrate 20 and the first unit circuit 100. In this case, the first unit circuit 100 may be disposed such that the insulating layer 14 is facing the fabric material 10.

The fabric material 10 may include a fiber fabric with no conductivity. The fabric material 10 may be one of various fabric products such as clothes, shoes, hats, etc. Also, the fabric material 10 may be a fiber fabric having a certain size, and have a type that is adhered to various fabric products.

The first unit circuit 100 is transferred onto the fabric material 10. In detail, the fabric material 10 may be coupled to the first unit circuit 100, and the carrier substrate 20 may be removed. In this case, when the insulating layer 14 is an adhesive layer, adhesive intensity between the fabric material 10 and the first unit circuit 100 can increase. Also, the release layer 16 can facilitate the removal of the carrier substrate 20 from the first unit circuit 100.

Referring to FIG. 4, the first unit circuit 100 may be formed on the fabric material 10. The first unit circuit 100 may include the first circuit pattern 12 disposed on the insulating layer 14 that is formed on the fabric material 10, and the first circuit pattern 12 is exposed to a surface of the insulating layer 14.

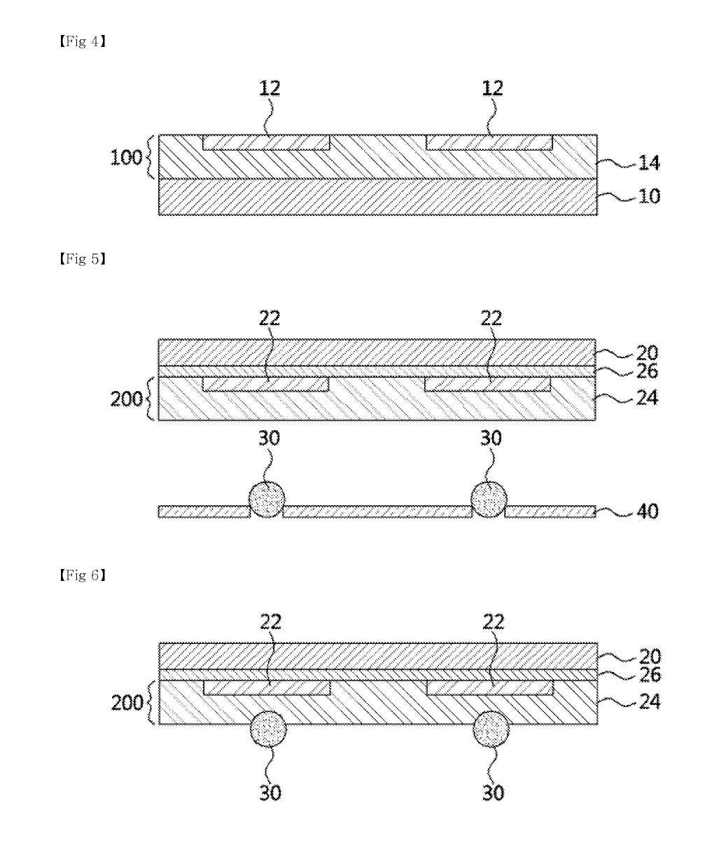

Referring to FIG. 5, the unit circuit UC (which has been described above with reference to FIGS. 1 and 2), namely, a second unit circuit 200 is provided. The second unit circuit 200, as described above with reference to FIGS. 1 and 2, includes a second circuit pattern 22 and an insulating layer 24. Furthermore, the second unit circuit 200 may be disposed on the carrier substrate 20, and a release layer 26 may be disposed between the carrier substrate 20 and the second unit circuit 200.

A mask layer 40 may be disposed on the insulating layer 24 of the second unit circuit 200. The mask layer 40 may have a plurality of holes corresponding to at least one portion of each of the second circuit patterns 22. The mask layer 40 may be a metal mask or a ceramic mask. The holes may be formed by photolithography and etching. However, the material of the mask layer 40 and a patterning process may be variously selected within the scope that is obvious to those skilled in the art.

Subsequently, a conductor 30 is disposed in the hole. For example, the conductor 30 may be a metal ball, and specifically, the conductor 30 may be a solder ball. The conductor 30 may be disposed in the hole by using squeegee. However, the conductor 30 may be variously disposed within the scope that is obvious to those skilled in the art.

Subsequently, the mask layer 40 and the insulating layer 24 are disposed to face each other.

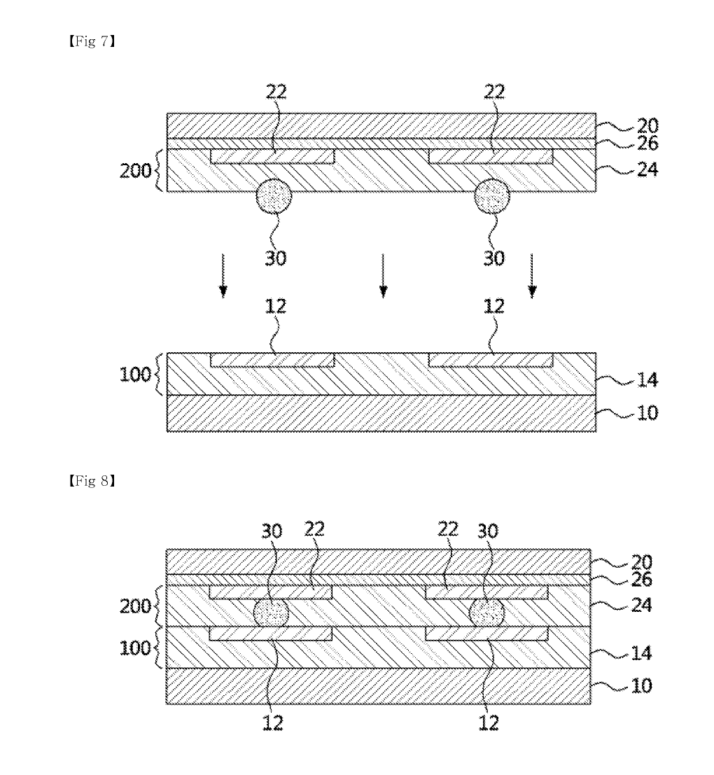

Referring to FIG. 6, by compressing the second unit circuit 200 and the mask layer 40, the conductor 30 is joined onto the insulating layer 24. The compression process may be a thermo-compression process. In this case, in the thermo-compression process, a temperature may be less than or equal to the melting point of the conductor 30.

As described above, when the insulating layer 24 is an adhesive resin layer, the conductor 30 may be adhered onto the insulating layer 24. On the other hand, before the conductor 30 is introduced, a separate adhesive layer (not shown) may be further formed on the insulating layer 24. When the temperature for the thermo-compression process is set to higher than or equal to the softening temperature of the adhesive resin layer, the conductor 30 may penetrate into a portion of the surface of the insulating layer 24. In performing the thermo-compression process, a process temperature may be variously set according to the physical properties of the insulating layer 24 and conductor 30 that are joined.

Subsequently, the mask layer 40 is removed. The mask layer 40 may be removed by an etching process. However, the present embodiment is not limited thereto, and the mask layer 40 may be removed by various processes within the scope that is obvious to those skilled in the art.

Unlike the above-described, the conductor 30 may be provided onto the first unit circuit 100.

Referring to FIGS. 7 and 8, the conductor 30 may be disposed between the first unit circuit 100 and the second unit circuit 200. In this case, the conductor 30 is introduced into the insulating layer 24 of the second unit circuit 200, and the first circuit pattern 12 of the first unit circuit 100 may be disposed to face the conductor 30.

Subsequently, the first unit circuit 100 and the second unit circuit 200 are compressed. Due to pressure that is given in the compression operation, the conductor 30 may penetrate into the insulating layer 24 and may be joined to the second circuit pattern 22. Furthermore, the compression may be thermo-compression. The thermo-compression may be performed through a vacuum heat press process. In this case, temperature for the thermo-compression process may be higher than or equal to the softening temperature of the insulating layer 24.

As described above, the insulating layers 14 and 24 included in the unit circuits 100 and 200 may have adhesiveness. Therefore, the insulating layer 14 of the first unit circuit 100 is adhered to the insulating layer 24 of the second unit circuit 200 through compression. The insulating layers 14 and 24 are disposed between the first and second unit circuits 100 and 200, and insulate layers. Also, the insulating layers 14 and 24 are charged between the first and second circuit patterns 12 and 22, and thus prevent a multilayer PCB from being stripped.

Moreover, since the insulating layer 24 is an adhesive resin layer, the insulating layer 24 near the conductor 30 is softened by heat that is generated in the compressing of the first and second unit circuits 100 and 200, and thus, the conductor 30 may penetrate into the insulating layer 24. Therefore, the conductor 30 reaches the second circuit pattern 22 that is disposed under the insulating layer 24, and is directly adhered to the first and second circuit patterns 12 and 22, in which case the circuit patterns 12 and 22 are connected electrically. In this case, for an efficient connection, distance between the first and second circuit patterns 12 and 22 may be shorter than the diameter of the conductor 30.

As described above, the conductor 30 is introduced into the insulating layer 24, and electrically connects the first and second circuit patterns 12 and 22. Accordingly, a separate hole for an electrical connection between layers is unnecessary.

Moreover, the conductor 30 is directly adhered to the first and second circuit patterns 12 and 22 and electrically connects the circuit patterns 12 and 22, thus enabling more precise junction. Furthermore, the conductor 30 is introduced into the insulating layers disposed between the unit circuits and supported by the insulating layer, and thus, even when a shape is deformed by the torsion of flexible fabrics, an electrical connection can be maintained.

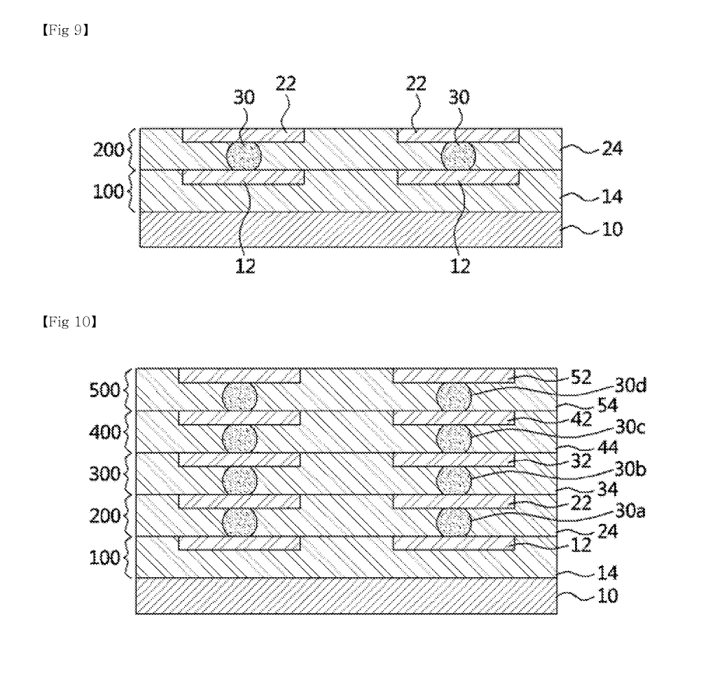

Referring to FIG. 9, the first unit circuit 100 is joined to the second unit circuit 200, and then the carrier substrate 20 disposed at one surface of the second unit circuit 200 may be removed. In this case, the release layer 26 formed at one surface of the carrier substrate 20 may be used.

A multilayer PCB according to another embodiment of the present invention will be described with reference to FIG. 9.

A fabric material 10 disposed at a base may include a fiber fabric with no conductivity. The fabric material 10 may be one of various fabric products such as clothes, shoes, hats, etc. Also, the fabric material 10 may be a fiber fabric having a certain size, and have a type that is adhered to various fabric products.

A first unit circuit 100 and a second unit circuit 200 stacked sequentially on the fabric material 10, the first unit circuit 100 includes a first circuit pattern 12, and the second unit circuit 200 includes a second circuit pattern 22.

The first circuit pattern 12 is disposed on an insulating layer 14, and the second circuit pattern 22 is disposed on an insulating layer 24. The shapes of the circuit patterns may be the same or differ.

The insulating layers 14 and 24 are disposed between the first and second unit circuits 100 and 200, and are charged between the first and second circuit patterns 12 and 22. Therefore, the insulating layers 14 and 24 insulate layers, and prevent a multilayer PCB from being stripped.

Each of the insulating layers 14 and 24 may be an adhesive resin layer. For example, the insulating layers 14 and 24 may contain a thermoplastic resin with adhesiveness. As an example, the thermoplastic resin may be polystyrene, polyethylene, polyallylate, or polycarbonate. However, the present embodiment is not limited thereto, and the insulating layers 14 and 24 may be formed of one selected from among various materials, within the scope that is obvious to those skilled in the art.

The conductor 30 is directly adhered to the first circuit pattern 12 of the first unit circuit 100 and the second circuit pattern 22 of the second unit circuit 200, and electrically connects the circuit patterns 12 and 22. Furthermore, the conductor 30 is introduced into the insulating layer 24 disposed between the first and second unit circuits 100 and 200 and supported by the insulating layer 24, and thus, even when a shape is deformed by the torsion of flexible fabrics, an electrical connection can be maintained.

The conductor 30 may be formed of a conductive material. For example, the conductor 30 may be a metal ball, and specifically, the conductor 30 may be a solder ball.

As described above, the method of manufacturing the multilayer PCB having two unit circuits is illustrated, but is not limited thereto. By repeatedly performing the operation that has been described above with reference to FIGS. 4 to 7, a multilayer PCB having three or more unit circuits may be formed.

FIG. 10 is a sectional view illustrating a fabric-type multilayer PCB including three or more unit circuits according to another embodiment of the present invention.

Referring to FIG. 10, a multilayer PCB may be formed by stacking a plurality of unit circuits 100, 200, 300, 400 and 500 on a fabric material 10. The number of unit circuits may be variously changed according to the kind of product made with fabrics. The unit circuits 100, 200, 300, 400 and 500 include a plurality of circuit patterns 12, 22, 32, 42 and 52, respectively. A plurality of insulating layers 14, 24, 34, 44 and 54 are charged between the circuit patterns 12, 22, 32, 42 and 52. In the insulating layer 24, a conductor 30a is directly joined to the circuit pattern 12 of the unit circuit 100 and the circuit pattern 22 of the unit circuit 200. In the insulating layer 34, a conductor 30b is directly joined to the circuit pattern 22 of the unit circuit 200 and the circuit pattern 32 of the unit circuit 300. In the insulating layer 44, a conductor 30c is directly joined to the circuit pattern 32 of the unit circuit 300 and the circuit pattern 42 of the unit circuit 400. In the insulating layer 54, a conductor 30d is directly joined to the circuit pattern 42 of the unit circuit 400 and the circuit pattern 52 of the unit circuit 500. A detailed description on each of the elements is as described above, and thus is not provided.

In this way, a conductor that is introduced into an insulating layer disposed between circuit patterns is directly joined to respective circuit patterns of upper and lower unit circuits, and thus electrically connects the circuit patterns.

As described above, the method of manufacturing the fabric-type multilayer PCB according to the present invention forms the multi-layer unit circuit on the fabric material, and thus can maintain wearability and flexibility of fabrics and enables electronic parts to be mounted on various products made with fabrics. Also, the method of the present invention introduces the conductor between the unit circuits and then couples the conductor to the unit circuits by applying compression, thus simplifying the manufacturing process and saving on manufacturing cost. Furthermore, a conductor is directly joined to the circuit patterns of each unit circuit, and thus, more precise junction is made, and electrical characteristics can be sufficiently shown with the flexibility of the fabric material.

Moreover, in the multilayer PCB according to the present invention, the circuit patterns of each unit circuit are physically and electrically connected by the conductor, and thus enables efficient electrical connection. Furthermore, the conductor is introduced into the insulating layer that is disposed between the circuit patterns of each unit circuit, and thus can be supported by the insulating layer, and even when a shape is deformed by the torsion of flexible fabrics, an electrical connection can be maintained.

While the example embodiments of the present invention and their advantages have been described in detail, it should be understood that various changes, substitutions and alterations may be made herein without departing from the scope of the invention.

What is claimed is:

1. A method of manufacturing a fabric-type multilayer printed circuit board (PCB), the method comprising:
providing a first unit circuit formed on a fabric material, a first circuit pattern being exposed on the first unit circuit;
providing an insulating layer and a second unit circuit that comprises a second circuit pattern disposed under the insulating layer;
providing a conductor between the first and second unit circuits; and
directly joining and electrically connecting the first and second circuit patterns by compressing the first and second unit circuits with the conductor therebetween to introduce the conductor into the insulating layer.

2. The method of claim 1, wherein the providing of a conductor comprises:
disposing a mask layer on the insulating layer, a a plurality of holes corresponding to the second circuit pattern being formed in the mask layer;
disposing the conductor in the hole of the mask layer;
joining the mask layer, in which the conductor is disposed, onto the insulating layer; and
removing the mask layer.

3. The method of claim 1, wherein the insulating layer is an adhesive resin layer.

4. The method of claim 3, wherein the insulating layer contains a thermoplastic resin.

5. The method of claim 1, wherein the compression is thermo-compression.

6. The method of claim 5, wherein,
the insulating layer is an adhesive resin layer, and
a temperature of the thermo-compression is higher than or equal to a softening temperature of the insulating layer.

7. The method of claim 1, wherein an operation of forming the second unit circuit comprises:
forming the second circuit pattern on a carrier substrate; and
forming the insulating layer on the second circuit pattern.

8. The method of claim 7, further comprising removing the carrier substrate of the second unit circuit after electrically connecting the first and second circuit patterns.

9. A fabric-type multilayer printed circuit board (PCB), comprising:
a fabric material;
a first unit circuit disposed on the fabric material, and comprising a first circuit pattern;
a second unit circuit disposed on the first unit circuit, and comprising a second circuit pattern;
an insulating layer charged between the first and second circuit patterns; and
a conductor joined directly to the first and second circuit patterns to electrically connect the first and second circuit patterns, in the insulating layer.

10. The fabric-type multilayer PCB of claim 9, wherein the insulating layer is an adhesive resin layer.
